(19) United States
(12) Patent Application Publication
(10) Pub. No.: US 2012/0253721 A1
(43) Pub. Date: Oct. 4, 2012

(54) DETERMINING CHARACTERISTICS OF ULTRASHORT PULSES

(75) Inventors: Jacob Cohen, Eindhoven (NL); Pamela Bowlan, Berlin (DE); Rick Trebino, Atlanta, GA (US)

(73) Assignee: GEORGIA TECH RESEARCH CORPORATION, Atlanta, GA (US)

(21) Appl. No.: 13/074,211

(22) Filed: Mar. 29, 2011

(51) Int. Cl. G01R 29/02; G01J 3/45

(52) U.S. Cl. 702/79; 356/451

(57) ABSTRACT

Various systems and methods for analysis of optical pulses are provided. In one embodiment, a method is provided including obtaining a plurality of traces produced by propagating an unknown pulse and a reference pulse along a pair of crossing trajectories through a spectrometer, where each trace is associated with a delay between the unknown pulse and the reference pulse. Each trace is spatially filtered to generate a plurality of spatially filtered electric field measurements, which are temporally filtered to generate a plurality of temporally filtered electric field measurements. The plurality of temporally filtered electric field measurements are concatenated based at least in part upon the delay associated with the corresponding trace to generate a concatenated wave form corresponding to the unknown pulse.

### STATEMENT REGARDING FEDERALLY SPONSORED RESEARCH OR DEVELOPMENT

### Background

In ultrafast optics laboratories it is often desirable to measure the spatial or temporal profile of ultrashort pulses. In some situations, separate spatial and temporal measurements are insufficient in order to obtain the desired profile, and complete spatio-temporal dependence of the pulse is needed. For example, a pulse can be contaminated by spatio-temporal distortions that limit the performance of an ultrafast system such as might be the case, for example, with amplified pulses. Alternatively, the pulse may have been used to excite or probe complex media with time-varying spatial structure. Indeed, spatial-temporal distortions are quite common, and only very carefully and precisely aligned pulses can be considered to be free of such distortions. Unfortunately, such precisely aligned pulses are generally obtained at significant cost and effort.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a drawing of an optical system employed to determine characteristics of an ultrashort pulse in accordance with various embodiments of the present disclosure.

FIGS. 2 and 3 illustrate pulse analysis based upon traces obtained with the optical system of FIG. 1 in accordance with various embodiments of the present disclosure.

FIGS. 4-8 are graphical representations illustrating characteristics of pulses determined using pulse analysis of FIG. 2 in accordance with various embodiments of the present disclosure.

FIG. 9 is a drawing of another optical system employed to determine characteristics of an ultrashort pulse in accordance with various embodiments of the present disclosure.

FIGS. 10-12 illustrate pulse analysis based upon single-shot traces obtained with the optical system of FIG. 9 in accordance with various embodiments of the present disclosure.

FIG. 13 is a schematic diagram of a processor-based system coupled to an image capture device employed in the optical systems of FIGS. 1 and 9 in accordance with various embodiments of the present disclosure.

FIG. 14 is a flow chart that provides one example of the operation of a pulse analysis system that analyzes interferogram traces obtained by the optical systems of FIGS. 1 and 9 in accordance with various embodiments of the present disclosure.

### DETAILED DESCRIPTION

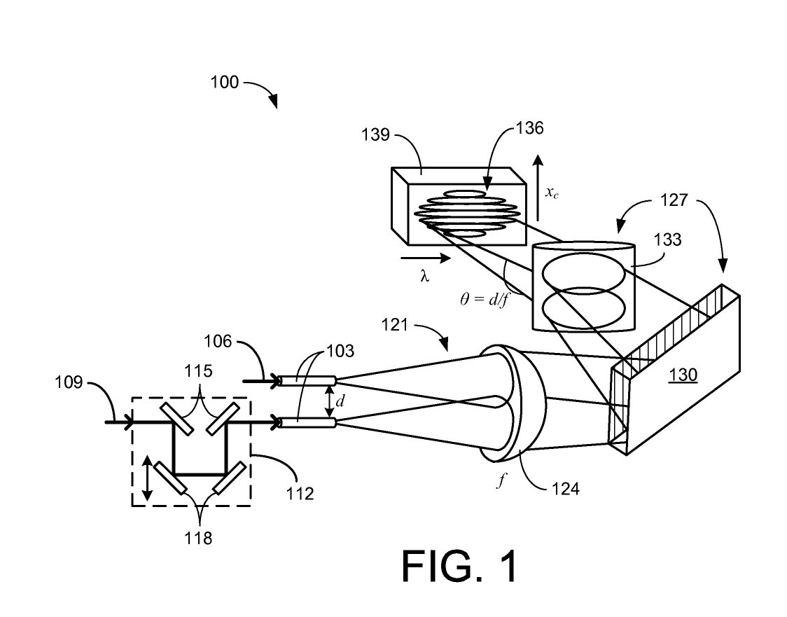

Referring to FIG. 1, shown is an example of an optical system 100 according to various embodiments of the present invention. The optical system 100 includes two equal-length single-mode optical fibers 103. A first input pulse 106 is coupled into one single-mode optical fiber 103 and a second input pulse 109 is coupled into the other single-mode optical fiber 103 through a delay stage 112, which provides a variable delay of the second input pulse 109. To this end, the delay stage 112 of the optical system 100 includes stationary mirrors 115 and adjustable mirrors 118 that allow variable delay of the second input pulse 109.

In order to redirect the propagation of the light beams 121 of the first and second pulses 106 and 109, a spherical lens 124 is employed. In the horizontal dimension, the light beams 121 of the input pulses 106 and 109 are collimated by the spherical lens 124. In the vertical dimension, the light beams 121 of the pulses 106 and 109 cross at a small angle and produce horizontal spatial fringes at an image capture device 139 included, for example, in a camera. The small angle θ at which the light beams of the pulses 106 and 109 cross may be determined by the distance d between the ends of the optical fibers 103 and the focal length f of the lens 133.

The light of the input pulses 106 and 109 is spectrally resolved by a spectrometer 127 including a grating 130 and a lens 133 into an interferogram trace 136 that is captured by the image capture device 139 included, for example, in a camera. Alternatively, the spectrometer 127 could include a curved grating, or any other spectrometer design well known to those skilled in the art. The image capture device 139 may comprise, for example, a charge coupled device (CCD) array or other image capture device as can be appreciated. Fourier-transforming the resulting trace 136 with respect to position (not frequency) and keeping only the ac term at the spatial-fringe frequency yields the pulse intensity and phase. Crossed-beam spectral interferometry is further discussed in U.S. Pat. No. 7,817,282, entitled “Use of crossed-beam spectral interferometry to characterize optical pulses” and issued on Oct. 19, 2010, the entirety of which is hereby incorporated by reference.

In one implementation, the first input pulse 106 is an unknown pulse and the second input pulse 109 is a reference pulse. In another implementation, the first input pulse 106 is the reference pulse and the second input pulse 109 is the unknown pulse. The unknown pulse may comprise, for example, an ultrashort laser pulse such as a pulse generated by a mode-locked laser or an amplifier, with a pulse duration in the femtosecond (fs) regime and a pulse energy in the nanojoule to millijoule range. For example, the unknown pulse may be an arbitrary complex waveform with duration of about one nanosecond and about 100 fs substructures. The reference pulse may also comprise, for example, an ultrashort laser pulse such as a pulse generated by a mode-locked laser or an amplifier, with pulse duration in the femtosecond regime and pulse energy in the attojoule to millijoule range. The reference pulse spectrum contains the spectrum of the unknown pulse.

The optical system 100 provides for the determination of the characteristics of the unknown pulse based upon a plurality of traces 136 associated with multiple delays of the second input pulse 109. Rather than using a single delay, many delays are used to obtain the traces 136. Specifically intended for measuring very long and complex pulses, the reference pulse only overlaps in time with a fraction of the temporal length of the unknown pulse and makes spatial fringes only with that temporal piece of the unknown pulse. Fourier-transforming the resulting trace 136 with respect to position and keeping only the ac term at the spatial-fringe frequency yields the pulse intensity and phase of the temporal piece of the unknown pulse that temporally overlaps with the reference pulse.

Varying the delay of the second pulse 109 yields a plurality of traces 136 for all temporal pieces of the long unknown pulse and so yields the complete intensity and phase of every temporal piece of the unknown pulse. Concatenating in time all the measured pieces of the unknown pulse reconstructs the entire pulse in time. It is important to remember that the reference pulse lengthens significantly in time inside the spectrometer 127, specifically, to the spectrometer's inverse spectral resolution. This is easily understood by considering that spectrometers map a small range of frequencies, δω, equal to the spectral resolution, to each pixel of the image capture device 136. From the uncertainty principle, such a narrow band of frequencies can only be contained in a pulse that has a temporal duration:

$${τ}_{sp} ≧ \frac{1}{δω} \qquad EQN ( 1 )$$

Therefore, the reference pulse broadens in time inside the spectrometer by the reciprocal of the spectrometer's spectral resolution, τₛₚ. So for each delay, a fairly long temporal piece of the unknown pulse is actually determined in one measurement. For example, a 20 fs reference pulse measures a temporal piece of an unknown pulse that is 10 ps long when using a spectrometer 127 with 100 GHz spectral resolution. Since the pulse measurement uses multiple reference pulses to oversample information at each time value, the delay spacing of successive reference pulses would only need to be about 3 picoseconds (ps), rather than 20 fs. The effective spectral resolution is therefore many times many times the spectral resolution of the spectrometer 127. Specifically, it is the reciprocal of the reference-pulse delay range. In other words, it can measure pulses as long as the delay that can be generated.

The maximum time-bandwidth product (TBP) offered by the optical system 100 is the spectral range of the spectrometer 127 divided by the inverse delay range. However, this may be further limited by the dynamic range of the image capture device 139. This is because, as the reference pulse only makes spatial fringes with the temporal piece of the unknown pulse with which it temporally overlaps, the rest of the unknown pulse also inevitably impinges on the image capture device 139, yielding a spatially structureless background of no value to that particular measurement and which may therefore be filtered out. While the relevant Fourier filtering works very well, this background noise could become very large for very complex pulses that are long compared to the spectrometer-broadened reference pulse. Thus, the dynamic range of the image capture device 139 poses a limit to the largest TBP measurable by the optical system 100. Using one count as the limit, the largest TBP measurable by the optical system 100 may be estimated as the product of the finesse of the spectrometer 127 (i.e., its spectral range divided by its resolution) and the dynamic range of the image capture device 139 used to make the measurement. If the image capture device 139 is chosen to match the spectrometer 127, i.e., its number of columns is equal to the spectrometer finesse, then the maximal TBP measurable with optical system 100 is the product of the number of columns (or rows, whichever is greater) and its dynamic range. Cameras can have a dynamic range of 16 bits or about 64,000, and as many as a few thousand columns. Thus, it may be possible to measure pulses with a TBP as large as 10⁸.

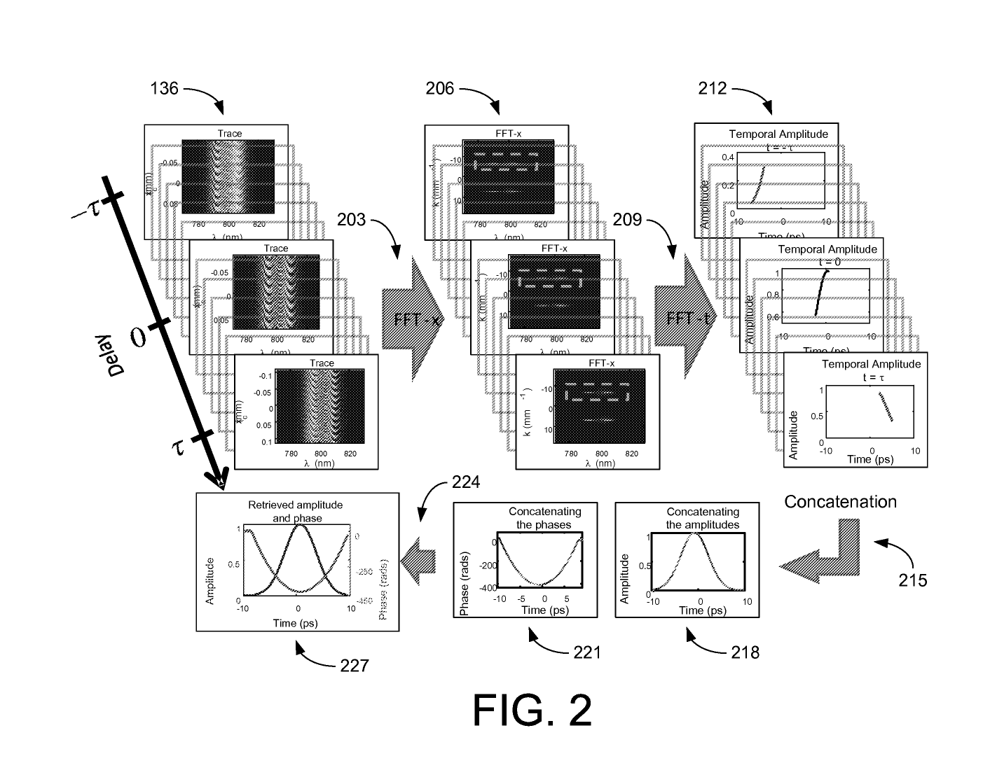

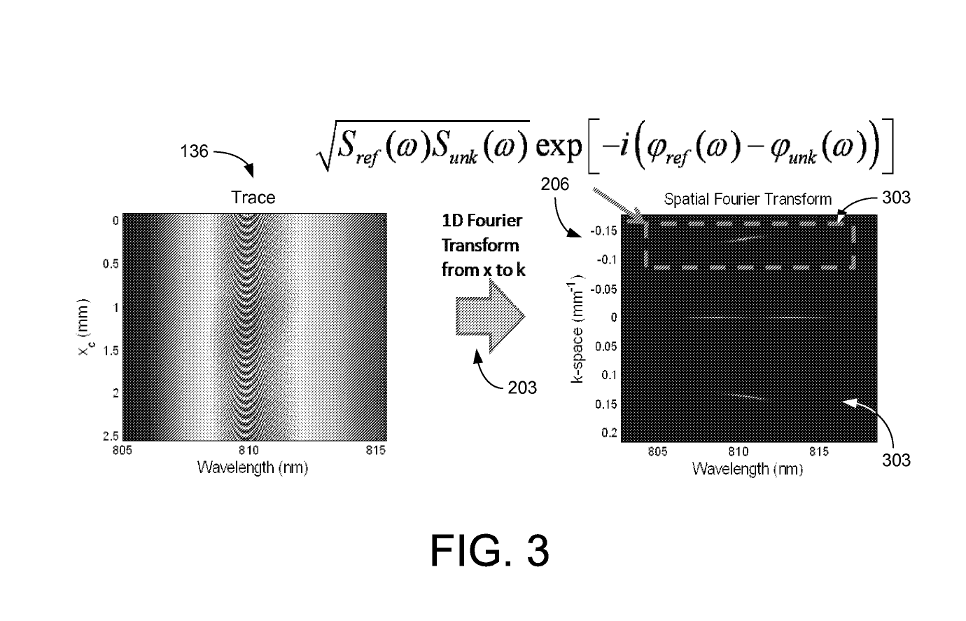

Referring next to FIG. 2, the determination of the characteristics of an unknown pulse is illustrated in accordance with various embodiments of the current disclosure. To begin, a plurality of traces 136 are obtained using the optical system 100 of FIG. 1. The delay stage 112 is used to delay the second pulse 109 in time, resulting in multiple traces 136 being captured by the image capture device 139 at different delays. A typical data set includes N traces 136 like the ones shown in FIG. 3.

The electric field of the unknown pulse is retrieved from a spectrally resolved spatial interferogram trace 136 resulting from the crossing of the two light beams 121 of the first and second pulses 106 and 109. Each measurement retrieves a different temporal section of the electric field of the unknown pulse, where the range of each individual measurement is τₛₚ, and is much shorter than the unknown pulse duration. The interferogram can be described by the following equation:

S(x_{c},ω)=S_{ref}(ω)+Sᵤₙₖ(ω)+2\sqrt{S_{ref}(ω)}\sqrt{Sᵤₙₖ(ω)} cos(2kx_{c} sin θ+φᵤₙₖ(ω)−φ_{ref}(ω) EQN (2)

where θ is half the beam crossing angle, and x_{c} is the spatial coordinate along the crossing dimension shown in FIG. 1.

The entire electric field of the unknown pulse, including both the phase and spectral amplitude, can be retrieved from EQN (2) by isolating the argument and amplitude of the cosine term. Each trace 136 corresponding to a different temporal slice is spatially Fourier filtered 203, resulting in the electric field at each delay, Eᵢ(ω). This is done by applying a one-dimensional Fourier transform 203 to each of the plurality of traces 136 along the x_{c}-dimension to produce a plurality of corresponding k-space transformations 206. Once in k-space, the phase and non-phase information (i.e., the first two terms in EQN. (2)) from the interferogram separate out as illustrated by the example in FIG. 3.

Referring now to FIG. 3, shown is an example of a trace 136 of a heavily chirped unknown pulse. Applying a one-dimensional Fourier transform 203 to the trace 136 along the x_{c}-dimension separates the data into three bands in the k-space transformation 206. The side-bands 303 contain both the spectral phase difference and the spectrum of the unknown pulse. Either side-band 303 may be isolated from the rest of the data and transformed back to the position domain using an inverse Fourier transform. This results in the product of the unknown and reference pulse complex fields. Additionally, using frequency-resolved optical gating (FROG), the phase of the field of the reference pulse can be measured, and divided out, thereby completely characterizing the unknown pulse.

Referring back to FIG. 2, illustrated are the multiple traces 136 included in the data set. Since the reference pulses are successively delayed in time by a constant, τ_{ref}, each retrieved spectrum, Sᵢ(ω), and spectral phase difference,

Δφᵢ(ω)=φᵤₙₖ_{ᵢ}(ω)−φ_{ref}_{ᵢ}(ω) EQN (3)

corresponds to a measurement of the unknown pulse at a different time, τᵢ. Here τᵢ is the delay between the reference and unknown pulse for the i^{th} trace 136. Each trace 136 combined with a FROG measurement of the reference pulse determines the spectral phase of the unknown pulse, φᵤₙₖ(ω), yielding the entire electric field,

Eᵢ(ω)=\sqrt{Sᵢ(ω)}e^{iφ}^{ᵢ}^{(ω)} EQN (4)

At the spectrometer 124 (FIG. 1), the duration of each reference pulse in time is given by τₛₚ. Each reference pulse interferes with the unknown pulse over a temporal width of τₛₚ. Therefore, each Eᵢ(ω), will contain spectral information about the unknown pulse in the time window,

$${τ}_{i} - \frac{{τ}_{sp}}{2} < t < {τ}_{i} + \frac{{τ}_{sp}}{2} \qquad EQN ( 5 )$$

yielding N measurements of the electric field of the unknown pulse, E_{i=1:N}(ω), centered about different times.

Constant background subtraction may also be performed before temporally filtering the data. A constant background may be subtracted from the measurements, which reduces the high frequency noise in the retrieved temporal amplitude and phase. For example, the maximum noise value may be subtracted from the retrieved measurements with any negative points that result from the subtraction set to zero.

Temporal filtering is then performed on each of the N measurements. The retrieved electric fields are Fourier transformed 209 from the spectral domain into the time domain, resulting in electric fields centered about each τᵢ. Because the reference pulse interferes with a section of the unknown pulse of length τₛₚ, which is smaller than the time-axis of the retrieved pulse, only information within this region is kept while that from larger and smaller times is discarded. Specifically, each electric field is cropped to the time window so that:

$${\tilde{E}}_{i} ( t ) = \{ \begin{matrix}{\tilde{E}}_{i} ( t ) & for {τ}_{i} - \frac{{τ}_{sp}}{2} < t < {τ}_{i} + \frac{{τ}_{sp}}{2} \\ 0 & otherwise\end{matrix} \qquad EQN ( 6 )$$

After temporally filtering 209, each retrieved electric field is shifted in time because the field retrieved by the i^{th} reference pulse, \tilde{E}ᵢ(t), is centered around t=0, the local zero time value of the reference pulse. In other words, the i^{th} retrieved field, \tilde{E}ᵢ(t), is measured in a time frame relative to the i^{th} reference pulse. To piece together the entire unknown pulse in time, the retrieved fields are transformed from the local time frame of each reference pulse to the lab frame in which all of the reference pulses occur at different times. This means that the i^{th} retrieved field, \tilde{E}ᵢ(t), is linearly shifted by τᵢ,

\tilde{E}ᵢ(t) [symbol] \tilde{E}_{i,lab}(t−τᵢ) EQN (7)

In FIG. 2, the N resulting temporal amplitude plots 212 over the different time intervals are illustrated. Although only the amplitudes plots 212 are shown, after re-phasing N temporal phase plots over the different time intervals are also retrieved.

The retrieved amplitude and phase are separately concatenated 215 using a weighted average, resulting in the retrieval of the characteristics of the entire unknown pulse. Although the spectrum and phase of the pulses from the mode-locked laser are quite stable, slight non-uniformity of the spatial fringes over a significant period of time, noise, and shot-to-shot jitter of the reference pulses can cause discontinuities when concatenating the fields. To reduce these discontinuities a weighted averaging scheme is utilized.

Since each \tilde{E}_{i,lab}(t−τᵢ) corresponds to an independent measurement by the i^{th} reference pulse from the laser, each retrieved field is weighted by a Gaussian weighting function with a half width at 1/e, τ_{G}, which is less than τₛₚ and centered on the i^{th} reference pulse:

$${G}_{i} ( t - {τ}_{i} ) = exp [ - {( \frac{t - {τ}_{i}}{{τ}_{G}} )}^{2} ] \qquad EQN ( 8 )$$

A Gaussian function may be used as the weighting function because the temporal response function is approximately Gaussian in form. The accuracy of the experimental results are unaffected by variation of the width of the Gaussian weighting function as long as the width is less than τₛₚ, and greater than or equal to the delay spacing between the reference pulses, τ_{ref}, e.g.,

τ_{ref}≦τ_{G}<τₛₚ EQN (9)

Because the delay between reference pulses, τ_{ref}, is less than τₛₚ, a given section of the unknown pulse is reliably retrieved by more than one reference pulse. Therefore, averaging together the redundant information obtains a better retrieval. However, due to the spectrometer's finite resolution, the accuracy of an individual measurement decreases as you move away from its temporal origin. The weighting function accounts for this. Therefore, a Gaussian (rather than square) weighting function is used to more heavily weigh information that originates from the temporal center of the individual measurements. Keeping the weighting function's width less than τₛₚ, assures that no information from delays greater than τₛₚ, are included in the average, because this information is outside the spectrometer's temporal window and therefore, not accurate. This process reduces the noise in the retrieval and helps to avoid discontinuities when concatenating the independent measurements together. Since τₛₚ is directly related to the spectral resolution of a spectrometer 127 (FIG. 1), it can be obtained by measuring the fringe contrast of interference spectra at different delays.

The retrieved fields are concatenated together by separating each \tilde{E}_{i,lab}(t−τᵢ) into its constituent phase and amplitude components,

\tilde{E}_{i,lab}(t−τᵢ)=Aᵢ(t−τᵢ)e^{iφ}^{ᵢ}^{(t-τ}^{ᵢ}⁾ EQN (10)

Before concatenating the phase, each measured phase, φᵢ(t−τᵢ), may be re-phased (i.e., its zeroth-order phase value is matched to that of the neighboring pulselet). The re-phasing adjusts for the lack of active stabilization in the interferometer, which exhibits a slow drift in the phase over the course of an entire scan sequence. Accordingly, the retrieved temporal phases have a different absolute phase, which is removed before concatenation. This can be done easily because the temporal sections of the unknown pulse measured by subsequent reference pulses overlap. Therefore, the absolute phase of two individual measurements of the same time are set equal, which effectively removes the effect of drift.

The re-phasing procedure uses the fact that the absolute temporal phase does not contain any frequency vs. time information. Therefore, before concatenating, the absolute phases, φ⁽⁰⁾ᵢ, where,

φᵢ₊₁(t−τᵢ)=φᵢ⁽⁰⁾+φᵢ⁽¹⁾(t−τᵢ)+φᵢ⁽²⁾(t−τᵢ)² EQN (11)

are re-phased. Specifically, the absolute phase of the i^{th}+1 retrieved field, φ⁽⁰⁾ᵢ₊₁, is set equal to that of the previous retrieved phase at the midway point between the two, or:

$${ϕ}_{i + 1}^{( 0 )} ( \frac{{τ}_{i + 1} + {τ}_{i}}{2} ) = {ϕ}_{i}^{( 0 )} ( \frac{{τ}_{i + 1} + {τ}_{i}}{2} ) \qquad EQN ( 12 )$$

The re-phasing is performed sequentially, beginning with φ₂ and ending with φ_{N}.

After re-phasing, both the phases, φᵢ(t−τᵢ), and amplitudes Aᵢ(t−τᵢ), are separately superposed using a weighted average, yielding the entire temporal amplitude (plot 218) and phase (plot 221) of the unknown pulse:

$$\begin{matrix}{A}_{final} ( t ) = \frac{{\sum }_{j = 1}^{N} {G}_{j} ( t - {τ}_{j} ) {A}_{j} ( t - {τ}_{j} )}{{\sum }_{i = 1}^{N} {G}_{i} ( t - {τ}_{i} )} & EQN ( 13 ) \\ {ϕ}_{final} ( t ) = \frac{{\sum }_{j = 1}^{N} {G}_{j} ( t - {τ}_{j} ) {ϕ}_{j} ( t - {τ}_{j} )}{{\sum }_{i = 1}^{N} {G}_{i} ( t - {τ}_{i} )} & EQN ( 14 )\end{matrix}$$

The product 224 of the amplitude 218 and phase 221 yields the entire temporal amplitude and phase of the unknown pulse:

\tilde{E}_{final}(t)=A_{final}(t)e^{iφ}^{_{final}}^{(t)} EQN (15)

as illustrated in FIG. 2 by, e.g., retrieved plot 227.

Experimental measurements were performed with the optical system 100 of FIG. 1 using a Coherent MIRA Ti:Sapphire oscillator. The pulses were centered at 805 nm, with a FWHM bandwidth of 6 nm. Using a Swamp Optics GRENOUILLE 8-50USB, the pulse was measured to have a temporal width of 168 fs. The “unknown” pulses were stretched to a FWHM length of 40 ps using a single-grating pulse compressor. A 250 mm focal-length spherical lens 124 (FIG. 1) to collimate and cross the beams 121 (FIG. 1) emanating from the fibers 103 (FIG. 1). Additionally, a 600 grooves/mm grating 130 (FIG. 1) and 200 mm focal-length lens 133 (FIG. 1) were used for mapping wavelength to position in the spectrometer 127 (FIG. 1). The delay stage 112 (FIG. 1) used was a Newport MFA Series Miniature Linear Stage with a Newport ESP100 single-axis controller.

In a first experimental measurement, the stretched 40 ps “unknown” pulse was measured using the optical system 100 to obtain 100 traces 133, which each had a different reference-pulse delay. In the experiment, a spectral resolution of τₛₚ=9.2 ps was measured, therefore a delay spacing between the reference pulses of τ_{ref}=1.46 ps was used to satisfy the condition that τ_{ref}<τₛₚ. This temporal spacing was chosen to provide a significant amount of overlap with neighboring reference pulses, thereby reducing discontinuities during the concatenation routine. The half width at 1/e of the weighting function was chosen to be equal to the temporal separation of the reference pulses, τ_{G}=1.46 ps.

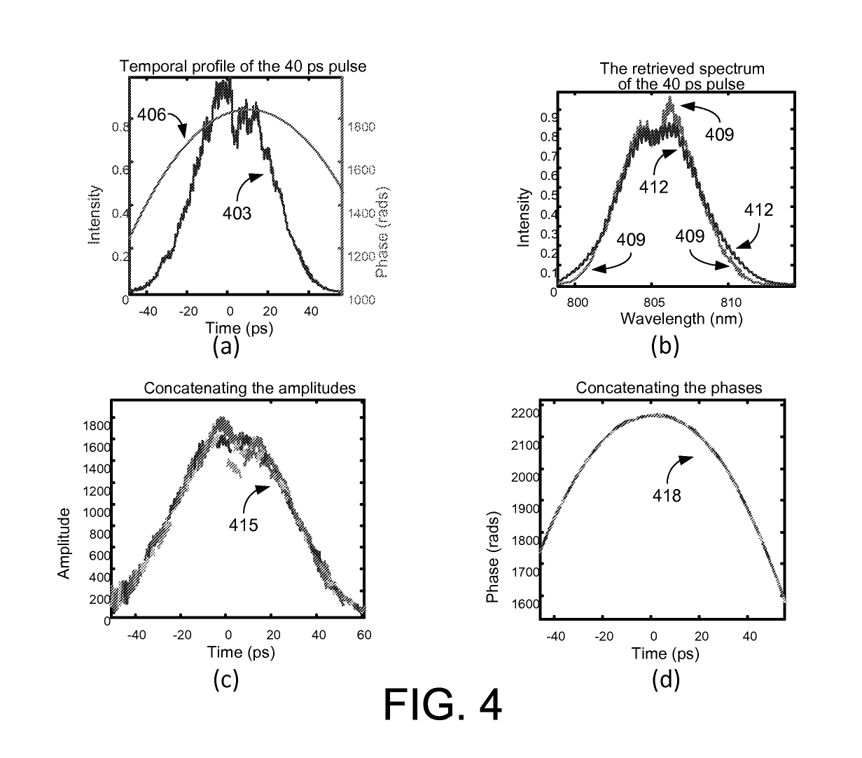

Referring to FIG. 4, the retrieved temporal amplitude 403 and phase 406 of the “unknown” 40 ps pulse is shown in FIG. 4(a). Since there is no commercial device capable of measuring the full intensity and phase of such a pulse, in FIG. 4(b) the retrieved spectrum 409 of the “unknown” pulse is compared to the independently measured spectrum 412 using an Ocean Optics HR 4000 spectrometer. As shown in FIG. 4(b), the Ocean Optics spectrometer provided enough spectral resolution to accurately measure the relatively smooth spectrum of the pulse. This is because the pulse compressor modifies the spectral phase rather than the spectral intensity. The result is that the linearly chirped pulse did not have finer spectral intensity features than the resolution of the spectrometer. Instead, the spectral phase of the chirped pulse contained the fine spectral features, which the spectrometer is unable to measure. In contrast, the optical system 100 is able to measure the phase 406, as demonstrated by the complete measurement of the temporal intensity and phase of the 40 ps pulse shown in FIG. 4(a).

As shown in FIG. 2, the amplitudes and phases were individually concatenated to characterize the “unknown” pulse. FIG. 4(c) shows the resulting concatenation of the retrieved temporal amplitudes Aᵢ(t−τᵢ) 415, illustrating the overlapping in time of the multiple measurements. FIG. 4(d) illustrates the concatentation of the retrieved temporal phases 418 after re-phasing, φᵢ(t−τᵢ). The retrieved amplitude 403 and phase 406 in FIG. 4(a) illustrate the effect of applying a weighted average to the concatenated amplitudes 415 and phases 418.

In a second experimental measurement, a “unknown” double pulse was generated by placing a Michelson interferometer after the single-grating pulse compressor. The bandwidth of the incident pulse was reduced to 3.4 nm in order to fit the entire “unknown” pulse within the temporal range of the optical system 100 (FIG. 1), which was limited by the scanning range of the delay stage 112 (FIG. 1). As a result, a 300 mm focal length cylindrical lens was used inside the spectrometer 127 (FIG. 1) to further spread out the reduced bandwidth on the image capture device 139. The reduced bandwidth of the incident pulse on the compressor resulted in the stretching of the incident pulse to 22 ps FWHM.

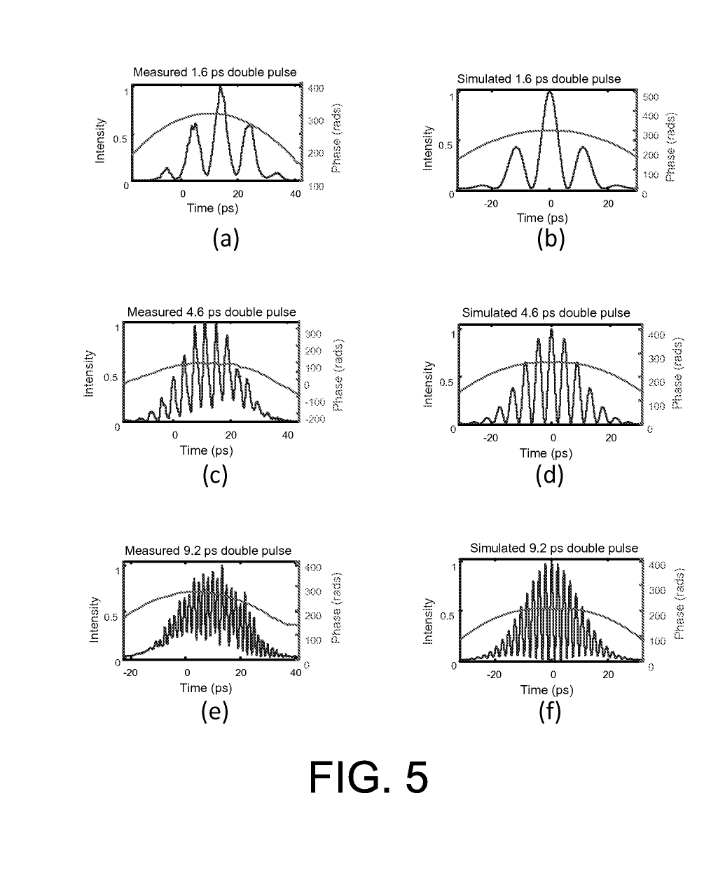

Referring to FIG. 5, shown are the measured and simulated temporal intensity and phase of two linearly chirped pulses at variable delays with respect to one another. FIG. 5 demonstrates a phenomena known as chirped pulse beating, which occurs because at each point in time the frequency content of each pulse differs by a constant beat frequency. This beat frequency is proportional to the delay, τ, between the two pulses.

FIGS. 5(a) and 5(b) illustrate the retrieved and simulated temporal profiles, respectively, of the two 22 ps linearly chirped pulses separated by 1.6 ps. FIGS. 5(c) and 5(d) illustrate the retrieved and simulated temporal profiles, respectively, after increasing the delay between pulses to 4.6 ps. FIGS. 5(e) and 5(f) illustrate the retrieved and simulated temporal profiles, respectively, after increasing the delay between pulses to 9.2 ps. FIGS. 5(g) and 5(h) illustrate the retrieved and simulated temporal profiles, respectively, after increasing the delay between pulses to 24 ps. At this large delay the temporal phase develops a cusp which the optical system 100 is able to retrieve. FIGS. 5(i) and 5(j) illustrate the retrieved and simulated temporal profiles, respectively, of a 50 ps double pulse. At such a large delay the temporal beating is not as noticeable as at much shorter delays because fewer frequencies are temporally overlapped.

In all examples of FIG. 5, the agreement between the retrieved and simulated results was good. FIG. 5 highlights the high temporal resolution and the large temporal range of the multiple delays for temporal analysis by dispersing a pair of light E-fields. In the experimental measurements, the spectrometer 127 had a spectral range of 30 nm and a temporal resolution of 71 fs. This high temporal resolution was utilized in the measurement of the double pulse with a 24 ps delay shown in FIG. 5(g). The fast temporal beating which had a temporal period of 622 fs was also well resolved by the measurement analysis. Using an optical power meter, the ratio of the intensities of the two pulses in the double pulse was determined to be 0.99, or almost equal. The measurement as shown in FIG. 5(i), where the intensities of the retrieved fields are shown to be roughly equal, confirms the measurement.

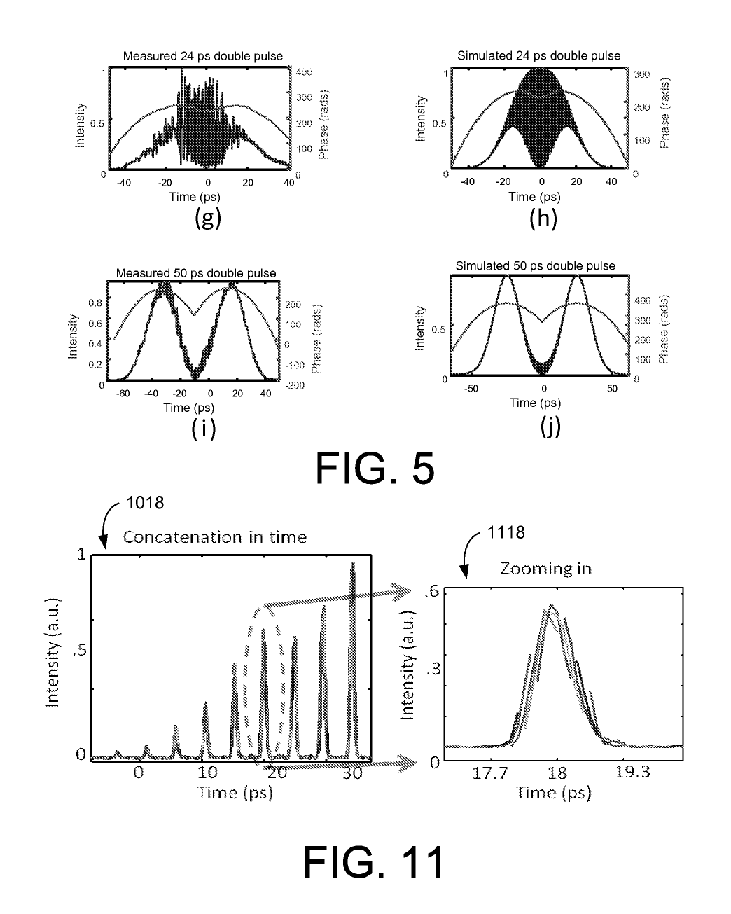

Referring next to FIG. 6, illustrated are the determined characteristics of a 50 ps chirped double pulse. FIG. 6(a) shows the retrieved temporal intensity 603 and phase 606 of the 50 ps chirped double pulse. In FIG. 6(b), the retrieved spectrum 609 is compared to an independently measured spectrum 612 using the Ocean Optics spectrometer. Since the two pulses are separated by such a large time delay, the spectral fringes are too fine for the high-resolution Ocean Optics spectrometer to resolve. The spectral fringes resulting from the double pulse when measured by a spectrometer with a 0.01 nm spectral resolution wash out completely at around 40 ps, while the analysis resolves them. Apart from the spectral fringes, FIG. 6(b) also illustrates that the envelope of the retrieved spectrum 609 and the spectrometer measured spectrum 612 agree.

Additionally, the measurement of the temporal phase of each of the pulses 606 is consistent with both pulses being chirped equally by the single grating pulse compressor. Although the chirp of the two pulses is not exactly the same due to the geometry of the Michelson interferometer, where one pulse makes three passes through a partially reflecting 1 cm beam splitter, while the other pulse makes only a single pass, this amount of added chirp is negligible compared to that introduced by the pulse compressor

As shown in FIG. 2, the amplitudes and phases were individually concatenated to characterize the “unknown” pulse. FIG. 6(c) shows the resulting concatenation of the retrieved temporal amplitudes Aᵢ(t−τᵢ) 615, illustrating the overlapping in time of the multiple measurements. FIG. 6(d) illustrates the concatentation of the retrieved temporal phases 618 after re-phasing, φᵢ(t−τᵢ). FIG. 6(d) also shows that the concatenation is able retrieve phases with cusps. The retrieved amplitude 603 and phase 606 in FIG. 6(a) illustrate the effect of applying a weighted average to the concatenated amplitudes 615 and phases 618.

Additional experimental measurements were performed with the optical system 100 of FIG. 1 using a KM Labs Ti:Sapphire oscillator. The pulses were centered at 800 nm, with a FWHM bandwidth of about 40 nm. Using a Swamp Optics GRENOUILLE 8-20USB, the input pulse was measured to have a temporal width of 285 fs. The pulses were stretched to a FWHM length of 70 ps using a grating pulse compressor. A 100 mm focal-length spherical lens 124 (FIG. 1) was used to collimate and cross the beams 121 (FIG. 1) emanating from the fibers 103 (FIG. 1). Additionally, a 600 grooves/mm grating 130 (FIG. 1) and 100 mm focal-length lens 133 (FIG. 1) were used for mapping wavelength to position in the spectrometer 127 (FIG. 1). The delay stage 112 (FIG. 1) used was a Newport M-IMS600CC Linear Stage with a Newport ESP300 single-axis controller. The total scanning range of the delay stage was 120 cm which provided a high spectral resolution

In a first experimental measurement, a double pulse consisting of two linearly chirped pulses stretched to 70 ps FWHM was measured using the optical system 100. Over the entire 120 cm scanning range, 2800 traces 133 were obtained, each having a different reference-pulse delay. The spectrometer 127 used here had half the spectral resolution and twice the spectral range of the previous setup described above. As a result, the reference pulse stretches in time from 256 fs to τₛₚ=4.6 ps inside the spectrometer compared to the previous τₛₚ=9.2 ps. The reference pulses were separated in time by τ_{ref}=1.46 ps. Since τ_{ref}<τₛₚ there was sufficient overlap with neighboring reference pulses, which minimized discontinuities during the concatenation routine. The half width at 1/e of the weighting function was chosen to be equal to the temporal separation of the reference pulses, τ_{G}=1.4 ps.

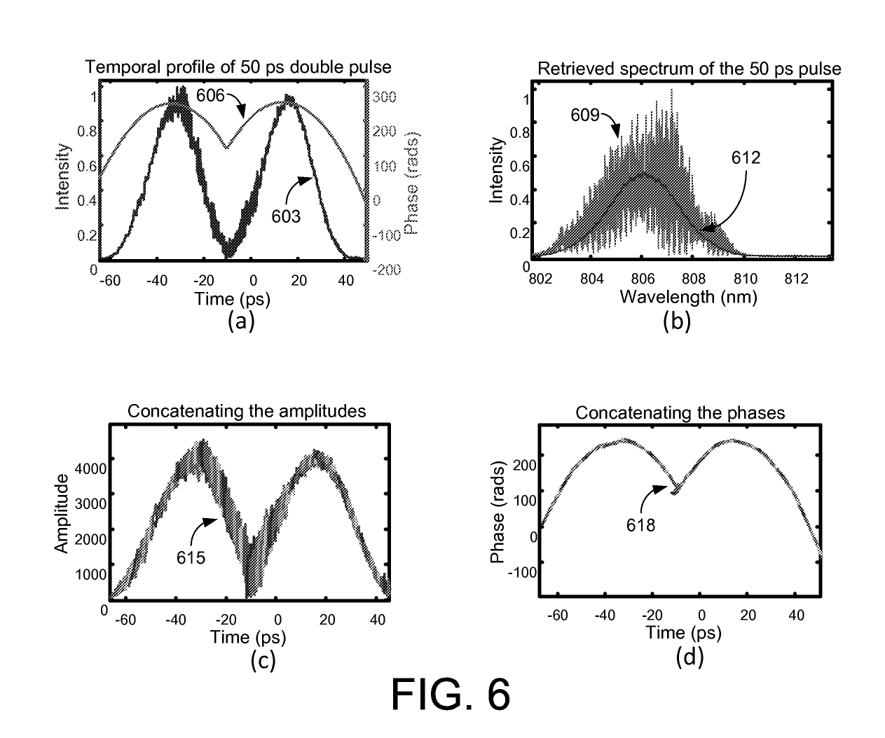

Referring now to FIG. 7, illustrated are the determined characteristics of a 70 ps chirped double pulse. FIG. 7(a) shows the retrieved spectrogram 703. The spectrogram 703 is an intuitive representation of the individual measurements at many delays and is easily computed from them. The slope of the lines 706 in the spectrogram 703 indicates that each pulse in the train is heavily chirped. The spectrogram 703 shows that each line 706 has the same slope indicating that each pulse has an identical chirp value. This is confirmed by FIG. 7(b) which shows the retrieved temporal profile 709 of the chirped double pulse, in which the temporal phase 712 of each pulse is almost identical. The ratio of the measured intensities 715 of each pulse in the double pulse was 0.6. Using a power meter, the ratio of the intensities of the two pulses in the double pulse was found to be 0.8. This discrepancy is likely due to misalignment of the Michelson interferometer, yielding better coupling of one pulse than the other into the optical fiber. In FIG. 7(c), the fringes of the intensity spectrum 718 are so fine that there is not sufficient spatial resolution to distinguish them. FIG. 2(d) depicts an enlarged region of the spectrum 718 to illustrate the ability to resolve a 5 pm spacing of the fringe.

In a second experimental measurement, a train of pulses was generated by placing a mirror pair, each with a 90% partially reflecting face, after a single-grating pulse compressor. The mirrors were not precisely parallel, but still yielded a train of pulses at their output. As in the previous experiment, each pulse in the pulse train had a FWHM temporal width of 70 ps and a FWHM spectral bandwidth of 40 nm.

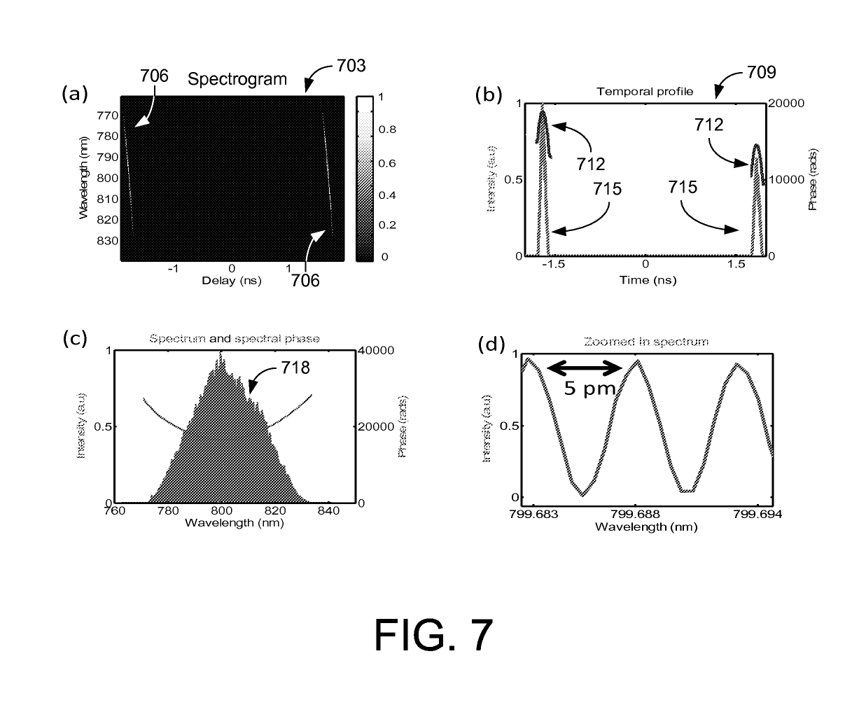

Referring next to FIG. 8, illustrated are the determined characteristics of a 70 ps pulse train. FIG. 8(a) shows the retrieved spectrogram 803 for the pulse train. As in the previous set of measurements, the slope of the lines 806 in the spectrogram 803 indicates that each pulse in the train is heavily chirped. This is confirmed by FIG. 8(b), which shows the retrieved temporal profile 809 of the pulse. The measured intensities 815 of the pulses in the pulse train decrease in time, as expected.

FIG. 8(c) shows the retrieved spectrum of the pulse train, which exhibits a large spectral range of about 50 nm in this measurement. In contrast to the intensity spectrum 718 of the chirped double pulse in FIG. 7(c), which has a Gaussian envelope, the intensity spectrum 818 shown in FIG. 8(c) is more complex. The unique shape may be attributed to two factors. First, the two partially reflecting mirrors were deliberately aligned not to be parallel, in order to avoid back reflections back into the laser. This slight misalignment results in a different temporal spacing between the adjacent pulses in the pulse train, which corresponds to different spectral-fringe periodicities in the spectral domain. This is in contrast to the measurement of the double pulse in which there is only one periodicity in the spectral fringes due to the single temporal spacing between the two pulses. Second, the absolute phase 812 of each individual pulse in the pulse train differed, which shifted the spectral fringes due to each pulse in the train of pulses, and which served to further distort the envelope of the spectrum.

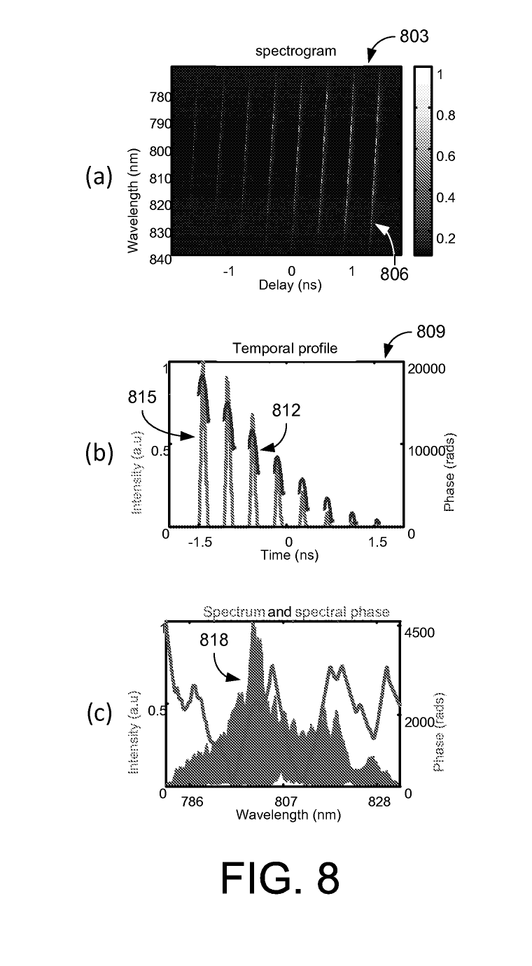

Referring to FIG. 9, shown is another example of an optical system 900 according to various embodiments of the present invention. Rather than using multiple reference pulses to scan the unknown pulse in time, a single reference pulse 912 is used to measure the entire unknown pulse 915 in time. In the example of FIG. 9, the optical system 900 includes a grating 903, an imaging lens 906 and a beam splitter 909. A reference pulse 912 is directed toward grating 903, which induces pulse-front tilt (PFT) of the reference pulse 912. The pulse-front of the spatially uniform reference pulse 912 is tilted along the horizontal dimension by the grating 903. The imaging lens 906 images the plane of the grating 903 into the spectrometer 127 ensuring that the only spatio-temporal coupling in the reference pulse 912 is PFT. While allowing the tilted pulse front to pass through, the beam splitter 909 redirects an unknown pulse 915 that is gated with the reference pulse 912 to provide the proper crossing angle. The unknown pulse 915 is incident on the spectrometer 127 at a slight angle, θ, with respect to the reference pulse. This crossing of the two pulses 912 and 915 results in spatial fringes along the x_{c}-dimension at the image capture device 139 of the imaging spectrometer.

The tilted pulse front provides a linear transverse time delay along the spatial dimension of the imaging spectrometer 127. The PFT of the reference pulse overlaps in time with the unknown pulse resulting in spacing of fringes at the image capture device 139. The result is N spectral measurements of the electric field of the unknown pulse 915, delayed in time by an amount proportional to the PFT, η. Provided that the range of delay generated, the product of the PFT and the spatial range of the imaging spectrometer, is greater than or equal to τᵤₙₖ, the temporal length of the unknown pulse 915, or η·Δx_{c}≧τᵤₙₖ, then the full temporal electric field of the unknown pulse 915 can be reconstructed by temporally interleaving the N linearly delayed measurements. A single-shot trace 936 is obtained including temporal information for the unknown pulse. Each row of the retrieved single-shot trace 936 corresponds to a measurement of the unknown pulse 912 with a different delay. The single-shot trace 936 is divided up into portions to obtain the temporal information at different delays. The temporal information obtained in the single-shot trace 936 using the optical system 900 of FIG. 9 is equivalent to the temporal information in the multiple traces obtained using the optical system 100 of FIG. 1. The same retrieval process may be applied to both to piece the temporal information together.

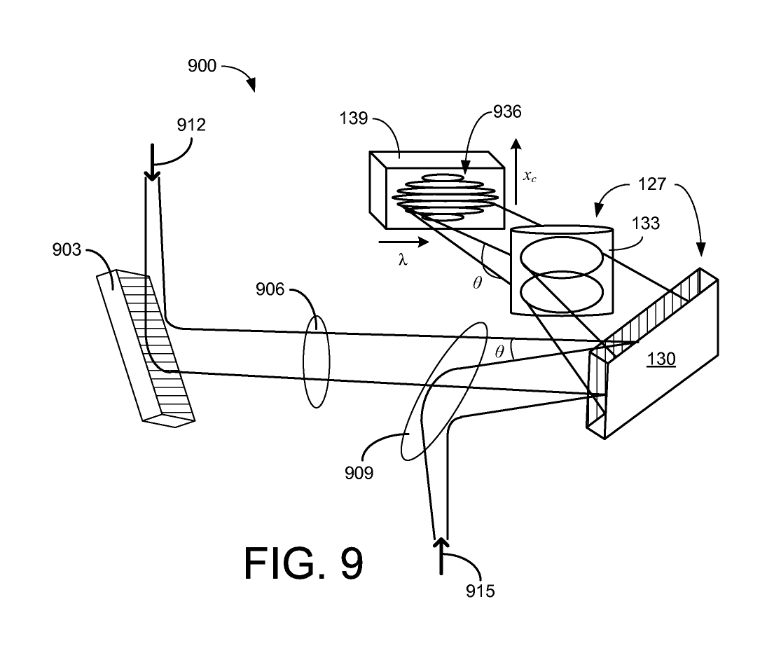

Referring next to FIG. 10, the determination of the characteristics of an unknown pulse is illustrated in accordance with various embodiments of the current disclosure. FIG. 10(a) is an example of a single-shot trace 936 of a 30 ps pulse train. The single-shot trace 936 is spatially Fourier filtered 1003. Applying a one-dimensional Fourier transform 1003 to the trace 936 along the x_{c}-dimension separates the data into three bands in the k-space transformation 1006 of FIG. 10(b). The side-bands contain both the spectral phase difference and the spectrum of the unknown pulse. The signal term (or side band) is filtered in kₓ-space and inverse Fourier transformed 1009 back to the spatial domain. FIG. 10(c) illustrates a field spectrogram 1012, where the spatial axis has been transformed to the delay axis because of the PFT of the reference pulse 912 (FIG. 9). The measurements are temporally filtered and concatenated 1015, as discussed with respect to FIG. 2, to retrieve the temporal electric field at the different delays. The concatenated temporal amplitude plot 1018 over the different time intervals is illustrated in FIG. 10(d). Although not shown, the same concatenation scheme is performed with the temporal phase. After performing a weighted average 1021 over all the retrieved sections of the amplitude 1018 and phase of the unknown pulse 915, the full temporal profile 1024 of the electric field of the unknown pulse 915 is retrieved as illustrated in FIG. 10(e).

Experimental measurements were performed with the optical system 900 of FIG. 9. In a first experimental measurement, a train of 9 pulses separated by about 4 ps were analyzed. The train of pulses was generated using an etalon composed of two partially reflecting mirrors with a reflectivity value of 90%. After the etalon, the pulse train was coupled into a 35 cm fiber optic cable to chirp the pulse.

Referring back to FIG. 10 (a), shown is a single-shot trace 936 obtained for the pulse train. The spatial fringes generated from the interference between the unknown pulse 915 (FIG. 9) and the reference pulse 912 (FIG. 9) is barely visible. But, taking a spatial Fourier transform 1003 clearly shows the resulting signal term (or side band) in the kₓ-space transformation 1006 of FIG. 10(b). After the signal term is filtered and shifted in kₓ-space, it is inverse Fourier transformed 1009 back to the spatial domain, where the amplitude of the reference pulse may be divided out.

The field spectrogram 1012 is shown in FIG. 10(c). The spatial dimension has been transformed to delay, because the PFT of the reference pulse 912 linearly maps position to delay on the image capture device 139 (FIG. 9). The calibration of the delay axis was determined using a double pulse of a known temporal spacing. The tilt of the spectrogram 1012 in FIG. 10(c) is due to the chirp of pulses in the pulse train which is expected because the pulse train was chirped by a 35 cm fiber. The temporal fringes in the spectrogram 1012 are due to the temporal overlap of the neighboring pulses.

Next, the spectrogram is Fourier transformed 1015 along the spectral dimension to the “time” domain, and temporally filtered 1015 keeping only the region in which the unknown pulse 915 and the reference pulse 912 are temporally overlapped. FIG. 10(d) shows how the delayed sections of the unknown pulse 915 are then concatenated 1015 in time resulting in the full temporal profile 1024 of the unknown pulse 915. The single-shot technique utilizing the PFT increased the temporal range/spectral resolution of the imaging spectrometer by a factor of nine.

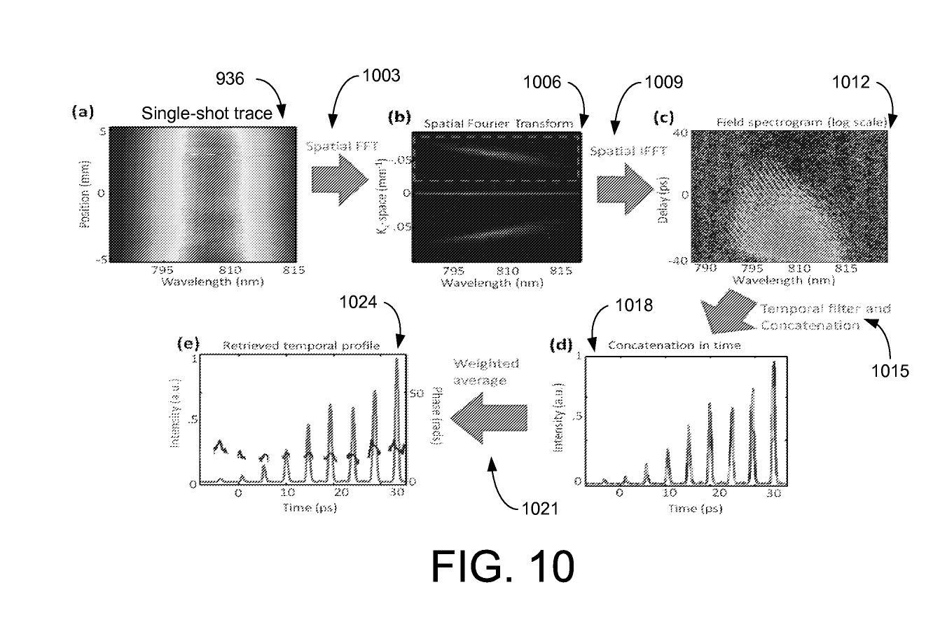

Referring to FIG. 11, shown is a zoomed in section of FIG. 10(d) of the fourth pulse in the pulse train located at the time value t=18 ps. The zoomed in section 1118 highlights the smooth concatenation of the different sections of the unknown pulse 912, illustrating “temporal interleaving” with fs temporal resolution.

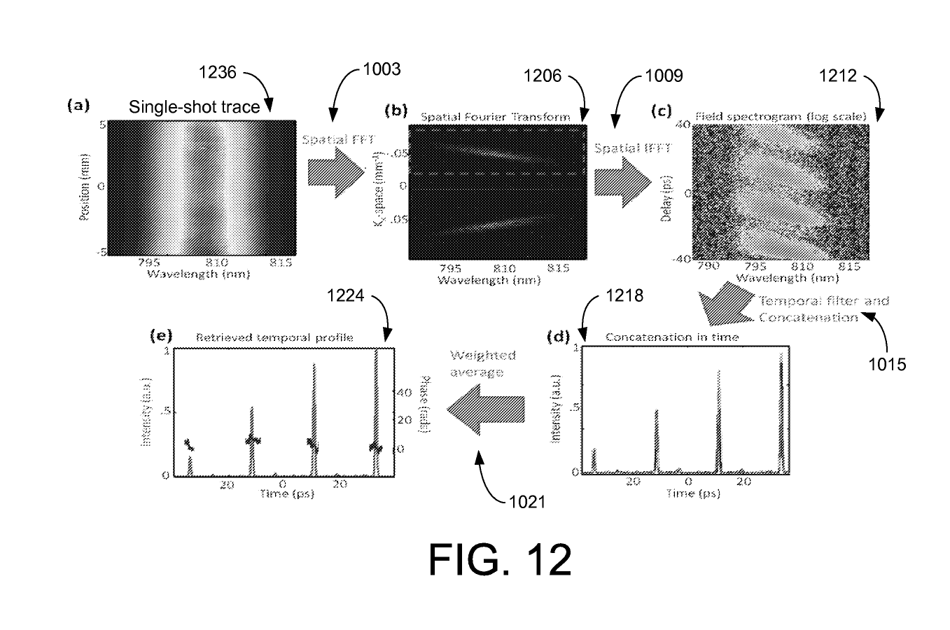

In a second experimental measurement. a 60 ps pulse train with temporal range of about 70 ps was analyzed. Referring to FIG. 12, the analysis is illustrated. FIG. 12(a) shows a single-shot trace 1236 obtained for the pulse train. The spatial Fourier transform 1003 of the trace 1236 is taken, resulting in the kₓ-space transformation 1206 of FIG. 12(b). Here the signal term is filtered in kₓ-space and inverse Fourier transformed 1009 back to the spatial domain. The spatial axis is transformed to the delay axis because of the PFT of the reference pulse 912 to produce the field spectrogram 1212 of FIG. 12(c). The spectrogram is Fourier transformed and temporally filtered 1015 to keep only the region in which the unknown pulse 915 and the reference pulse 912 are temporally overlapped. FIG. 10(d) shows how the delayed sections of the unknown pulse 915 are then concatenated 1015 in time. The concatenated temporal amplitude plot 1218 over the different time intervals is illustrated in FIG. 12(d). Although not shown, the same concatenation is performed to obtain the temporal phase. After performing a weighted average 1021 over all the retrieved sections of the amplitude and phase of the unknown pulse 915, the full temporal profile 1224 of the electric field of the unknown pulse 915 is retrieved.

While not evident from the single-shot traces 936/1236 and the kₓ-space transformation 1006/1206 of FIGS. 10 and 12, the field spectrogram 1212 shown in FIG. 12(c) is noticeably different from the field spectrogram 1012 of FIG. 10(c). The reason for this is that the pulses in the second pulse train of FIG. 12 are spaced 5 times further apart than the pulse train of FIG. 10 of about 20 ps. Therefore, neighboring pulses in the pulse train of FIG. 12 are not temporally overlapped and no interference fringes result. Additionally, the field spectrogram 1212 clearly shows a tilt for each pulse in the pulse train resulting from the chirp introduced by the 35 cm fiber. The single-shot technique utilizing the PFT increased the temporal range/spectral resolution of the imaging spectrometer by a factor of fifteen.

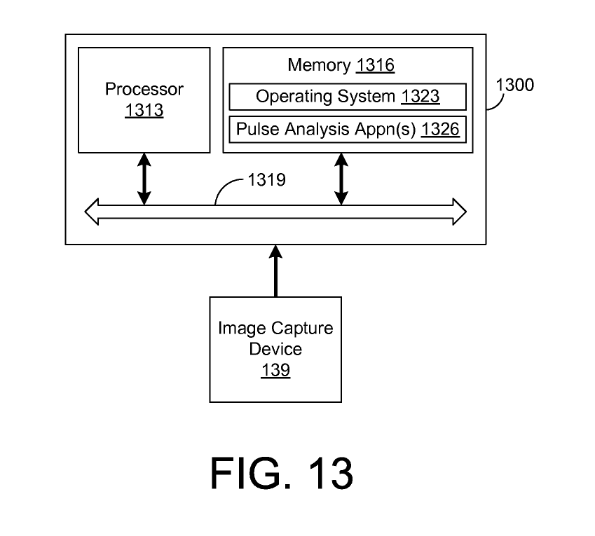

Turning then to FIG. 13, shown is a block diagram of a computer system 1300 that is attached to the image capture device 139 according to an embodiment of the present invention. The computer system 1300 may comprise, for example, a computer, server, dedicated processing system, or other system as can be appreciated. The computer system 1300 may include various input devices such as a keyboard, microphone, mouse, or other device as can be appreciated. The computer system 1300 includes a processor circuit having a processor 1313 and a memory 1316, both of which are coupled to a local interface 1319. The local interface 1319 may be, for example, a data bus with a control/address bus as can be appreciated.

Stored on the memory 1316 and executable by the processor 1313 are an operating system 1323 and a pulse analysis application(s) 1326. The pulse analysis application(s) 1326 are executed in order to determine a profile of the electric field E(x, y, ω) of the unknown pulse. The pulse analysis application(s) 1326 may comprise, for example, one or more applications executed to perform various functionality. Such applications may comprise, for example, Matlab, LabView or any compiled code.

The components stored in the memory 1316 may be executable by the processor 1313. In this respect, the term “executable” refers to a program file that is in a form that can ultimately be run by the processor 1313. Examples of executable programs may be, for example, a compiled program that can be translated into machine code in a format that can be loaded into a random access portion of the memory 1316 and run by the processor 1313, or source code that may be expressed in proper format such as object code that is capable of being loaded into a of random access portion of the memory 1316 and executed by the processor 1313, etc. An executable program may be stored in any portion or component of the memory 316 including, for example, random access memory, read-only memory, a hard drive, compact disk (CD), floppy disk, or other memory components.

The memory 1316 is defined herein as both volatile and nonvolatile memory and data storage components. Volatile components are those that do not retain data values upon loss of power. Nonvolatile components are those that retain data upon a loss of power. Thus, the memory 1316 may comprise, for example, random access memory (RAM), read-only memory (ROM), hard disk drives, floppy disks accessed via an associated floppy disk drive, compact discs accessed via a compact disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (MRAM) and other such devices. The ROM may comprise, for example, a programmable read-only memory (PROM), an erasable programmable read-only memory (EPROM), an electrically erasable programmable read-only memory (EEPROM), or other like memory device.

In addition, the processor 1313 may represent multiple processors and the memory 1316 may represent multiple memories that operate in parallel. In such a case, the local interface 1319 may be an appropriate network that facilitates communication between any two of the multiple processors, between any processor and any one of the memories, or between any two of the memories, etc. The processor 1313 may be of electrical or optical construction, or of some other construction as can be appreciated by those with ordinary skill in the art.

The operating system 1323 is executed to control the allocation and usage of hardware resources such as the memory, processing time and peripheral devices in the computer system 1300. In this manner, the operating system 1323 serves as the foundation on which applications depend as is generally known by those with ordinary skill in the art.

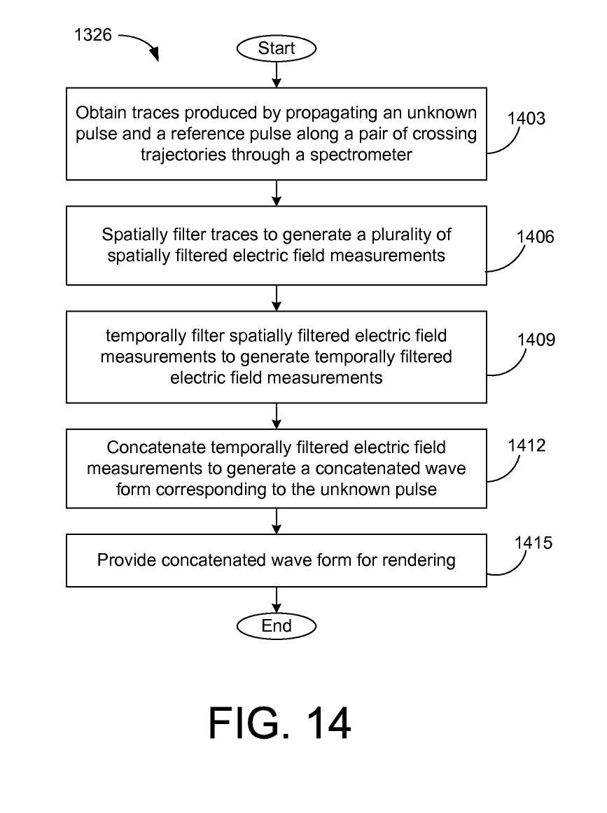

Referring next to FIG. 14, shown is a flow chart that provides one example of the operation of a pulse analysis application 1326 according to an embodiment of the present invention. Alternatively, the flow chart of FIG. 14 may be viewed as depicting steps of an example of a method implemented in the computer system 1300 to analyze an interferogram trace 136 (FIG. 1) or a single-shot interferogram trace 936 (FIG. 9) generated on the image capture device 139 as will be described. The functionality of the pulse analysis application 1326 as depicted by the example flow chart of FIG. 14 may be implemented, for example, in an object oriented design or in some other programming architecture. Assuming the functionality is implemented in an object oriented design, then each block represents functionality that may be implemented in one or more methods that are encapsulated in one or more objects. The pulse analysis application 1326 may be implemented using any one of a number of programming languages such as, for example, C, C++, or other programming languages. Alternatively, the pulse analysis application 1326 may comprise, for example, such applications as Matlab, LabView or any compiled code.

Beginning with block 1403, a plurality of traces is obtained. The traces are produced by propagating an unknown pulse and a reference pulse along a pair of crossing trajectories through a spectrometer. For example, the optical system 100 of FIG. 1 may be used to capture the traces 136, which are obtained by the computer system 1300 for pulse analysis. Alternatively, the optical system 900 of FIG. 9 may be used to capture a single-shot trace 936. The single-shot trace 936 is divided up into portions to corresponding to the plurality of traces. In some implementations, the traces 136/936 are captured and stored in memory. The stored traces 136/936 may be obtained for subsequent pulse analysis.

The traces are each spatially filtered in block 1406 to generate a plurality of spatially filtered electric field measurements. Each of the spatially filtered electric field measurements corresponds to one of the plurality of traces. In one implementation, spatially filtering includes applying a Fourier transform to each of the plurality of traces to generate a plurality of corresponding k-space transformations. A side-band of each of the k-space transformations is isolated and used to generate spatially filtered electric field measurements by applying an inverse Fourier transform. In some embodiments, constant background subtraction may also be performed to reduce the high frequency noise.

In block 1409, each of the plurality of spatially filtered electric field measurements is temporally filtered to generate a plurality of temporally filtered electric field measurements. For example, a Fourier transform may be to each of spatially filtered electric field measurements to generate a plurality of electric field measurements in the time domain, which are cropped based upon a time window corresponding to the time duration of the reference pulse to generate the plurality of temporally filtered electric field measurements.

A concatenated wave form corresponding to the unknown pulse is generated in block 1412 by concatenating the temporally filtered electric field measurements. The concatenation of the temporally filtered electric field measurements may be based, at least in part, upon the delay associated with each corresponding trace. In one implementation, each of the temporally filtered electric field measurements is shifted in time based, at least in part, upon the delay associated with the corresponding trace. The concatenated wave form corresponding to the unknown pulse may then be generated by weighted averaging of the shifted temporally filtered electric field measurements.

The concatenated wave form may then be provided for rendering on a display device associated with the computing system 1300. Alternatively, the concatenated wave form may be stored in memory for later retrieval and rendering.

Although the example of the pulse analysis application 1326 set forth above is depicted as being embodied in software or code executed by general purpose hardware as discussed above, as an alternative the same may also be embodied in dedicated hardware or a combination of software/general purpose hardware and dedicated hardware. If embodied in dedicated hardware, the pulse analysis application 1326 can be implemented as a circuit or state machine that employs any one of or a combination of a number of technologies. These technologies may include, but are not limited to, discrete logic circuits having logic gates for implementing various logic functions upon an application of one or more data signals, application specific integrated circuits having appropriate logic gates, programmable gate arrays (PGA), field programmable gate arrays (FPGA), or other components, etc. Such technologies are generally well known by those skilled in the art and, consequently, are not described in detail herein.

The flow chart of FIG. 14 shows the functionality and operation of one example implementation of a pulse analysis application 1326. If embodied in software, each block may represent a module, segment, or portion of code that comprises program instructions to implement the specified logical function(s). The program instructions may be embodied in the form of source code that comprises human-readable statements written in a programming language or machine code that comprises numerical instructions recognizable by a suitable execution system such as a processor in a computer system or other system. The machine code may be converted from the source code, etc. If embodied in hardware, each block may represent a circuit or a number of interconnected circuits to implement the specified logical function(s).

Although the flow chart of FIG. 14 shows a specific order of execution, it is understood that the order of execution may differ from that which is depicted. For example, the order of execution of two or more blocks may be scrambled relative to the order shown. Also, two or more blocks shown in succession in FIG. 14 may be executed concurrently or with partial concurrence. In addition, any number of counters, state variables, warning semaphores, or messages might be added to the logical flow described herein, for purposes of enhanced utility, accounting, performance measurement, or providing troubleshooting aids, etc. It is understood that all such variations are within the scope of the present invention.

Also, where the example pulse analysis application 1326 comprises software or code, it can be embodied in any computer-readable medium for use by or in connection with an instruction execution system such as, for example, a processor in a computer system or other system. In this sense, the logic may comprise, for example, statements including instructions and declarations that can be fetched from the computer-readable medium and executed by the instruction execution system. In the context of the present invention, a “computer-readable medium” can be any medium that can contain, store, or maintain the pulse analysis application 1326 for use by or in connection with the instruction execution system. The computer readable medium can comprise any one of many physical media such as, for example, electronic, magnetic, optical, or semiconductor media. More specific examples of a suitable computer-readable medium would include, but are not limited to, magnetic tapes, magnetic floppy diskettes, magnetic hard drives, or compact discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

It should be emphasized that the above-described embodiments of the present invention are merely possible examples of implementations set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and the present invention and protected by the following claims.

Therefore, having thus described the invention, at least the following is claimed:

1. A method, comprising:
obtaining, in a computer system, a plurality of traces, each trace produced by propagating an unknown pulse and a reference pulse along a pair of crossing trajectories through a spectrometer, the reference pulse having a time duration less than the unknown pulse, each trace associated with a delay between the unknown pulse and the reference pulse;
spatially filtering, in the computer system, each of the plurality of traces to generate a plurality of spatially filtered electric field measurements, each spatially filtered electric field measurement corresponding to one of the plurality of traces;
temporally filtering, in the computer system, each of the plurality of spatially filtered electric field measurements to generate a plurality of temporally filtered electric field measurements, each temporally filtered electric field measurement corresponding to one of the plurality of spatially filtered electric field measurements; and
concatenating, in the computer system, the plurality of temporally filtered electric field measurements based at least in part upon the delay associated with the corresponding trace to generate a concatenated wave form corresponding to the unknown pulse.

2. The method of claim 1, wherein the concatenated wave form is intensity of the unknown pulse with respect to time.

3. The method of claim 1, wherein the concatenated wave form is phase of the unknown pulse with respect to time.

4. The method of claim 1, wherein each of the plurality of traces corresponds to a trace produced by propagating the unknown pulse and one of a plurality of reference pulses along the pair of crossing trajectories through the spectrometer, each of the plurality of reference pulses corresponding to a different delay with respect to the unknown pulse.

5. The method of claim 4, wherein each of the plurality of reference pulses are successively delayed in time by a constant delay spacing.

6. The method of claim 1, wherein each of the plurality of traces corresponds to a portion of a single-shot trace produced by propagating the unknown pulse and a reference pulse having pulse-front tilt (PFT) along the pair of crossing trajectories through the spectrometer.

7. The method of claim 1, wherein spatially filtering each of the plurality of traces comprises:
applying a Fourier transform to each of the plurality of traces to generate a plurality of corresponding k-space transformations;
isolating a side-band of each of the plurality of k-space transformations; and
generating the plurality of spatially filtered electric field measurements by applying an inverse Fourier transform to each of the isolated side-bands.

8. The method of claim 1, wherein temporally filtering each of the plurality of spatially filtered electric field measurements comprises:
applying a Fourier transform to each of the plurality of spatially filtered electric field measurements to generate a plurality of electric field measurements in the time domain; and
generating the plurality of temporally filtered electric field measurements by cropping the electric field measurements in the time domain based upon a time window corresponding to the time duration of the reference pulse.

9. The method of claim 1, wherein concatenating the plurality of temporally filtered electric field measurements comprises:
shifting in time each of the temporally filtered electric field measurements based at least in part upon the delay associated with the corresponding trace; and
generating the concatenated wave form corresponding to the unknown pulse by weighted averaging of the plurality of shifted temporally filtered electric field measurements.

10. An apparatus, comprising:
a first optical fiber through which an first pulse propagates;
a second optical fiber through which a second pulse propagates;
a delay stage configured to variably delay the propagation of the second pulse through the second optical fiber;
a spectrometer, wherein the first and second pulses are directed from the first and second optical fibers into the spectrometer, wherein the first pulse and the second pulse propagate along a pair of crossing trajectories through the spectrometer to form an interferogram trace corresponding to the delay of the second pulse; and
an image capture device configured to capture the interferogram trace.

11. The apparatus of claim 10, wherein first and second optical fibers are positioned to direct the propagation of the first and second pulses along a pair of parallel trajectories.

12. The apparatus of claim 11, further comprising a lens positioned at the outlets of the first and second optical fibers, the lens redirecting the propagation of the first and second pulses from the parallel trajectories to the crossing trajectories.

13. The apparatus of claim 10, wherein the first pulse is an unknown pulse and the second pulse is a reference pulse.

14. The apparatus of claim 13, wherein the image capture device is configured to capture a plurality of interferogram traces, each interferogram trace associated with a delay between the unknown pulse and the reference pulse.

15. The apparatus of claim 14, further comprising a pulse analysis system operatively coupled to the image capture device, the pulse analysis system configured to determine a phase and intensity as functions of time for at least a portion of the unknown pulse from the plurality of interferogram traces.

16. The apparatus of claim 15, wherein the pulse analysis system determines the phase and intensity for the unknown pulse from the plurality of interferogram traces.

17. An apparatus, comprising:
a grating configured to induce pulse-front tilt in a reference pulse;
a beam splitter configured to redirect an unknown pulse along a crossing trajectory with respect to the reference pulse;
a spectrometer, wherein the reference pulse and unknown pulse are directed into the spectrometer, wherein the reference pulse and the unknown pulse propagate along a pair of crossing trajectories through the spectrometer to form a single-shot interferogram trace; and
an image capture device configured to capture the single-shot interferogram trace.

18. The apparatus of claim 17, further comprising a pulse analysis system operatively coupled to the image capture device, the pulse analysis system configured to determine a phase and intensity as functions of time for at least a portion of the unknown pulse from the single-shot interferogram trace.

19. The apparatus of claim 18, wherein the pulse analysis system determines the phase and intensity based upon a plurality of portions of the single-shot interferogram trace, each portion associated with a delay in the pulse-front tilt of the reference pulse.
